(19) United States
(12) Patent Application Publication
(10) Pub. No.: US 2014/0345664 A1
(43) Pub. Date: Nov. 27, 2014

(54) THERMOELECTRIC GENERATOR MODULE, METAL-CERAMIC SUBSTRATE AND METHOD OF PRODUCING SUCH A METAL-CERAMIC SUBSTRATE

(71) Applicant: Curamik Electronics GmbH, Eschenbach (DE)

(72) Inventors: Andreas Meyer, Wenzenbach (DE); Jurgen Schulz-Harder, Lauf (DE)

(73) Assignee: Curamik ElectronicsGmbH, Eschenbach (DE)

(21) Appl. No.: 14/368,372

(22) PCT Filed: Jan. 22, 2013
(86) PCT No.: PCT/DE2013/100020

§ 371 Date: Jun. 24, 2014

(30) Foreign Application Priority Data
Jan. 31, 2012 (DE) 102012100757.2
Mar. 13, 2012 (DE) 102012102090.6

(51) Int. Cl. H05K 1/03; H05K 3/00; H01L 35/30; H05K 1/11

(52) U.S. Cl. CPC H05K 1/0306; H05K 1/11; H05K 3/0067; H01L 35/30; H05K 2201/10219; H05K 2201/06
USPC 136/205; 174/255; 29/846

(57) ABSTRACT

The invention relates to a thermoelectric generator module with a hot zone and a cold zone including at least a first metal-ceramic substrate, which has a first ceramic layer and at least one structured first metallization applied to the first ceramic layer and is assigned to the hot zone, and at least a second metal-ceramic substrate, which has a second ceramic layer and at least one structured second metallization applied to the second ceramic layer and is assigned to the cold zone, and also a number of thermoelectric generator components located between the first and second structured metallizations of the metal-ceramic substrates. The first metal-ceramic substrate, assigned to the hot zone, has at least one layer of steel or high-grade steel, wherein the first ceramic layer is arranged between the first structured metallization and the at least one layer of steel or high-grade steel. The invention also relates to an associated metal-ceramic substrate and to a method for producing it.

### BACKGROUND OF THE INVENTION

The invention relates to a thermoelectric generator module to an associated metal-ceramic substrate, and to a method for producing a metal-ceramic substrate.

The mode of operation of thermoelectric generators is known in principle. A heat flow is produced by means of a temperature difference between the hot and cold zone of a thermoelectric generator component and is converted via the thermoelectric generator component into electrical energy. Thermoelectric generator components produced from a thermoelectric semiconductor material are preferably used for this purpose.

The use of thermoelectric generators for the direct conversion of heat into electrical energy is currently being examined in the automotive industry, for example in order to recover electrical energy for the internal vehicle energy system from the residual heat of the exhaust gases. In accordance with initial findings, the fuel consumption of the vehicle could thus be reduced significantly.

A problem here, however, is the arrangement of such thermoelectric generator components produced from a thermoelectric semiconductor material in the exhaust gas zone of the vehicle, in particular in the zone of the exhaust gas system. Thermoelectric generators or thermoelectric generator modules with a high resistance to temperature change that can reliably withstand temperature fluctuations in particular between 40° C. and 800° C. in the exhaust gas or hot zone are necessary for this purpose.

Further, a wide range of embodiments of metal-ceramic substrates, preferably in the form of printed circuit boards, are known, which for example have at least one ceramic layer and at least one metallisation applied to one of the surface sides of the ceramic layer, wherein the metallisation is structured to form conductive tracks, contact zones or fastening zones.

For example, the “DCB” (direct copper bonding) method is known for the connection of metal layers or sheets, preferably copper sheets or foils, to one another and/or to ceramic or ceramic layers, more specifically with use of metal or copper sheets or metal or copper foils that, on the surface sides thereof, have a layer or a coating (“melt layer”) formed from a chemical compound of the metal and a reactive gas, preferably oxygen. In this method, described by way of example in U.S. Pat. No. 3,744,120 or in DE-PS 23 19 854, this layer or this coating (“melt layer”) forms a eutectic system with a melting point below the melting point of the metal (for example copper), such that, by applying the metal foil or copper foil to the ceramic and by heating all layers, these layers can be interconnected, more specifically by melting the metal or copper substantially only in the zone of the melt layer or oxide layer. A DCB method of this type then comprises the following method steps by way of example:
oxidising of a copper foil in such a way that a uniform copper oxide layer is produced;
applying the copper foil with the uniform copper oxide layer to the ceramic layer;
heating the composite to a process temperature between approximately 1025 to 1083° C., for example to approximately 1071° C.;
cooling to room temperature.

Further, the “active solder method” is known from documents DE 22 13 115 and EP-A-153 618 for the connection of metal layers or metal foils forming metallisations, and in particular also of copper layers or copper foils, to a ceramic material or a ceramic layer. In this method, which is used specifically also to produce metal-ceramic substrates, a connection is produced between a metal foil, for example copper foil, and a ceramic substrate, for example an aluminium nitride ceramic, at a temperature between approximately 800-1000° C. with use of a hard solder, which, in addition to a main component such as copper, silver and/or gold, also contains an active metal. This active metal, which for example is at least one element from the group Hf, Ti, Zr, Nb, Ce, produces a connection between the hard solder and the ceramic as a result of a chemical reaction, whereas the connection between the hard solder and the metal is a metallic hard solder connection.

Thermoelectric generator components in the form of what are known as Peltier elements are also known, which with current flow generate a temperature difference, or, in the presence of a temperature difference generate a current flow. A Peltier element of this type basically comprises two cuboidal semiconductor elements, which have a different energy level, that is to say are either p-conducting or n-conducting, and are interconnected on one side via a metal bridge. Here, the metal bridges simultaneously also form the thermal connection areas, which are preferably applied to a ceramic and are thereby insulated from one another. A p-conducting and n-conducting cuboidal semiconductor element are therefore interconnected in each case via a metal bridge, more specifically in such a way that a series connection of the Peltier elements is produced.

Proceeding from the art mentioned above, it is an object of the invention to present a thermoelectric generator module and an associated metal-ceramic substrate and a method for production thereof, said thermoelectric generator module having a high resistance to temperature change and in particular enabling an arrangement of thermoelectric generator components in the exhaust gas zone of a motor vehicle.

### SUMMARY OF THE INVENTION

One key aspect of the thermoelectric generator module according to the invention with a hot zone and cold zone having at least one first metal ceramic substrate, which is assigned to the hot zone and has a first ceramic layer and at least one structured metallisation applied to the first ceramic layer, and comprising at least one second metal ceramic substrate, which is assigned to the cold zone and has a second ceramic layer and at least one second structured metallisation applied to the second ceramic layer, and also including a number of thermoelectric generator components received between the first and second structured metallisation of the metal-ceramic substrates lies, inter alfa, in that the first metal-ceramic substrate assigned to the hot zone has at least one steel layer or high-grade steel layer, wherein the first ceramic layer is arranged between the first structured metallisation and the at least one steel layer or high-grade steel layer. By means of the steel layer or high-grade steel layer provided in the hot zone of the thermoelectric generator module according to the invention, a simple and reliable attachment of the module in the exhaust gas zone of a motor vehicle, in particular to or in the zone of the exhaust gas system of a motor vehicle, is particularly advantageously made possible. By way of example, the module can be directly attached to the exhaust of a motor vehicle via the steel layer or high-grade steel layer.

In a development of the invention, the thermoelectric generator module according to the invention is formed by way of example in such a way that at least one copper layer is provided between the first ceramic layer and the at least one steel layer or high-grade steel layer, and/or the second metal-ceramic substrate assigned to the cold zone has at least one corrosion-resistant metal layer, the second ceramic layer being arranged between the second structured metallisation and the corrosion-resistant metal layer.

The corrosion-resistant metal layer is formed by a high-grade steel layer, aluminium layer or copper layer, and/or the first and second metallisation are structured in such a way that they form a number of metal contact areas, which are preferably rectangular and/or square.

The longitudinal sides of a rectangular metal contact area are approximately twice as long as the broad sides thereof, and/or the longitudinal sides of the rectangular metal contact areas run parallel to the module transverse axis, and the broad sides of the rectangular metal contact areas run parallel to the module longitudinal axis.

The longitudinal sides are between 0.5 mm and 10 mm, and the broad sides are between 0.2 mm and 5 mm, and/or the metal contact areas are arranged in a matrix-like manner on the surface side of the respective ceramic layer.

The rectangular metal contact areas form rows running parallel to the module longitudinal axis and columns running parallel to the module transverse axis, and/or two adjacent rectangular metal contact areas have a spacing from 0.1 mm to 2 mm in the direction of the module transverse axis.

Two adjacent rectangular metal contact areas have a spacing from 0.1 mm to 2 mm in the direction of the module longitudinal axis.

The above-mentioned features being applicable in each case individually or in any combination.

In an advantageous variant of the thermoelectric generator module according to the invention, separation lines or predetermined break lines are introduced into the ceramic layer between the preferably rectangular metal contact areas arranged at a distance from one another on the respective ceramic layer, said lines preferably running in the direction of the module transverse axis and/or in the direction of the module longitudinal axis. These lines may be produced advantageously in the form of slits, notches and/or scores, the depth of the slits, notches and/or scores of a separation line or predetermined break line extending at least over a quarter of the layer thickness of the respective ceramic layer starting from the surface side of a ceramic layer receiving the metallisation. Material breaks in the ceramic caused by high temperature fluctuations can particularly advantageously be absorbed in a controlled manner due to the introduction of separation lines or predetermined break lines, such that, even if the ceramic layer should break, the functionality of the thermoelectric generator module continues to be ensured.

In a development of the invention, the thermoelectric generator module according to the invention is formed by way of example in such a way that the ceramic layer is produced from aluminium oxide, aluminium nitride, silicon nitride or aluminium oxide with zirconium oxide, and preferably has a layer thickness in the range between 0.1 mm and 1.0 mm.

The first and second structured metallisation are configured in the form of metal layers or metal foils, more specifically preferably from copper or a copper alloy, which preferably have a layer thickness in the range between 0.03 mm and 1.5 mm.

The metallisations are provided at least in part with a metal surface layer, more specifically for example a surface layer formed from nickel, silver or a nickel alloy or silver alloy.

The thermoelectric generator components are configured in the form of Peltier elements produced from a differently doped semiconductor material, the layer thickness of the semiconductor material preferably being between 0.5 mm and 8 mm.

The aforementioned features being usable in each case individually or in any combination.

In a further advantageous variant of the thermoelectric generator module, the thermal conductivity and reliability are improved as a result of the fact that the steel layer or high-grade steel layer and/or the corrosion-resistant metal layer is/are configured in a number of parts, at least two parts of the steel layer or high-grade steel layer and/or of the corrosion-resistant metal layer being distanced from one another in such a way that at least one externally freely accessible surface portion of the ceramic layer is produced and/or the steel layer or high-grade steel layer and/or the corrosion-resistant metal layer is/are structured or profiled and/or the steel layer or high-grade steel layer and/or the corrosion-resistant metal layer has/have a peripheral bead in a zone protruding outwardly beyond the edge region of the ceramic layer.

The aforementioned features again being usable in each case individually or in any combination.

The invention also relates to a metal-ceramic substrate for use in a thermoelectric generator module, comprising at least one ceramic layer and at least one structured metallisation applied to the ceramic layer, in which at least one steel layer or high-grade layer is particularly advantageously provided, the ceramic layer being arranged between the structured metallisation and the at least one steel layer or high-grade steel layer.

In an advantageous development, the metal-ceramic substrate is formed by way of example in such a way that at least one copper layer is provided between the ceramic layer and the at least one steel layer or high-grade steel layer.

The metallisation is structured in such a way that it forms a number of metal contact areas, which are preferably rectangular and arranged at a distance from one another.

The longitudinal sides of a rectangular metal contact area are approximately twice as long as the broad sides thereof, the longitudinal sides preferably being between 0.5 mm and 10 mm, and the broad sides preferably being between 0.2 mm and 5 mm.

The metal contact areas are arranged in a matrix-like manner on the surface side of the ceramic layer, more specifically in rows and columns, and/or separation lines or predetermined break lines are introduced into the ceramic layer between the metal contact areas and are preferably produced in the form of slits, notches and/or scores, and/or the slits, notches and/or scores of a separation line or predetermined break line extend over a quarter of the layer thickness of the ceramic layer starting from the surface side of a ceramic layer receiving the metallisation.

The ceramic layer is produced from aluminium oxide, aluminium nitride, silicon nitride or aluminium oxide with zirconium oxide and preferably has a layer thickness in the range between 0.1 mm and 1.0 mm.

The structured metallisation is configured in the form of a metal layer or metal foil, more specifically preferably from copper or a copper alloy which preferably has a layer thickness in the range between 0.03 mm and 1.5 mm.

The metallisation is provided at least in part with a metal surface layer, more specifically for example a surface layer formed from nickel, silver or a nickel alloy or silver alloy.

The aforementioned features being usable in each case individually or in any combination.

The invention also relates to a method for producing a metal-ceramic substrate, in particular in the form of a printed circuit board for a thermoelectric generator module, comprising at least one ceramic layer and at least one structured metallisation applied to the ceramic layer, in which at least one steel layer or high-grade steel layer is applied directly or indirectly to the surface opposite the ceramic layer.

The method according to the invention is configured by way of example such that the metallisation is structured in such a way that a number of rectangular metal contact areas are formed and are preferably arranged in a matrix-like manner on the ceramic layer, and/or separation lines or predetermined break lines are introduced into the ceramic layer between the rectangular metal contact areas by means of laser treatment or sawing, more specifically preferably in the form of slits, notches and/or scores.

The ceramic layer formed from aluminium oxide, aluminium nitride, silicon nitride or aluminium oxide with zirconium oxide and the metallisation produced by a copper layer or copper alloy are connected by DOB bonding.

The steel or high-grade steel layer is directly connected to the ceramic layer by hard soldering, active soldering or adhesive bonding.

The aforementioned features being usable in each case individually or in any combination.

The expressions “approximately”, “substantially” or “for example” in the context of the invention mean deviations from the exact value by +/−10% in each case, preferably by +/−5%, and/or deviations in the form of changes insignificant for function.

Developments, advantages and possible applications of the invention will also emerge from the following description of exemplary embodiments and from the figures. Here, all described features and/or features illustrated schematically are fundamental to the subject matter of the invention individually or in any combination.

### BRIEF DESCRIPTION OF THE DRAWINGS

The invention will be explained in greater detail hereinafter with reference to the figures illustrating exemplary embodiments, in which:

FIG. 1 shows a simplified sectional illustration of a thermoelectric generator module according to the invention,

FIG. 2 shows a simplified illustration of a plan view of the structured metallisation of the metal-ceramic substrate assigned to the hot side,

FIG. 3 shows a simplified sectional illustration of an alternative variant of the thermoelectric generator module according to FIG. 1,

FIG. 4 shows a simplified sectional illustration of a further alternative variant of the thermoelectric generator module according to FIG. 3,

FIG. 5 shows a simplified sectional illustration of a thermoelectric generator module comprising two metal-ceramic substrate arrangements according to FIG. 1,

FIG. 6 shows a simplified sectional illustration of a thermoelectric generator module comprising a stack of two metal-ceramic substrate arrangements according to FIG. 1,

FIG. 7 shows a simplified sectional illustration of a thermoelectric generator module comprising alternative embodiment of a stack of two metal-ceramic substrate arrangements according to FIG. 6,

FIG. 8 shows a simplified sectional illustration of a thermoelectric generator module concerning an alternative embodiment of the thermoelectric generator module according to FIG. 3,

FIG. 9 shows a simplified sectional illustration of a thermoelectric generator module with a structured steel layer or high-grade steel layer and/or corrosion-resistant metal layer,

FIG. 10 shows a schematic plan view of a grid-like steel layer or high-grade steel layer or corrosion-resistant metal layer with different grid patterns,

FIG. 11 shows a simplified sectional illustration of a thermoelectric generator module concerning an alternative embodiment of the thermoelectric generator module according to FIG. 1, and

FIG. 12 shows a simplified sectional illustration of a thermoelectric generator module concerning an alternative embodiment of the thermoelectric generator module according to FIG. 3 with peripheral bead.

### DETAILED DESCRIPTION OF THE INVENTION

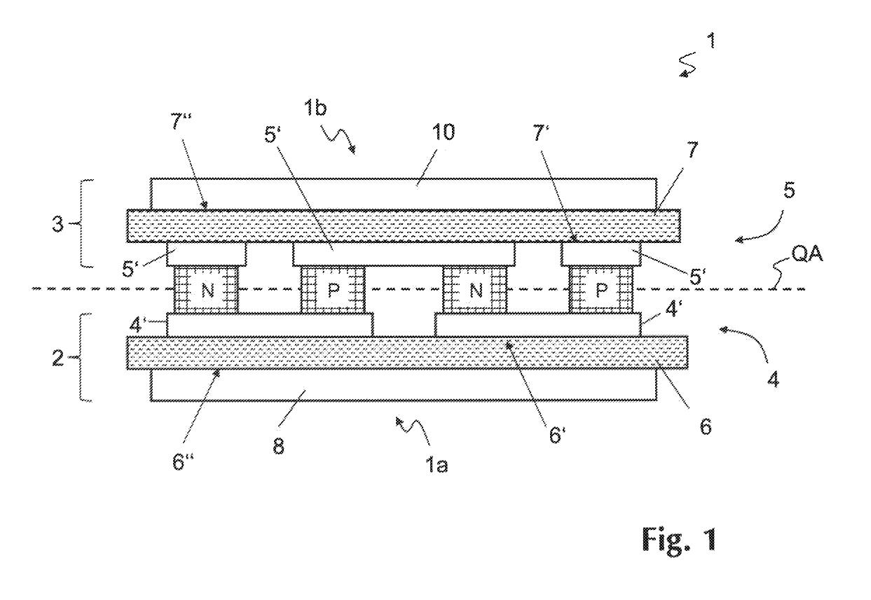

FIG. 1, in a simplified illustration, shows a section through a thermoelectric generator module 1 according to the invention with a hot zone 1a and a cold zone 1b, which comprises substantially two preferably plate-like metal-ceramic substrates 2, 3, which are provided on the mutually opposed surfaces thereof with a structured metallisation 4, 5. With use of the thermoelectric generator module 1 according to the invention in the automotive industry, the hot zone 1a can be exposed to temperature fluctuations between 40° C. and 800° C., and the cold zone 1b can be exposed to temperature fluctuations between 40° C. and 125° C.

Each structured metallisation 4, 5 forms a plurality of preferably opposite contact areas 4′, 5′, the structured metallisations 4, 5 having a layer thickness between 0.03 mm and 0.6 mm, for example.

Differently doped thermoelectric generator components N, P are received between the opposite structured metallisations 4, 5 of the metal-ceramic substrates 2, 3, and more specifically each thermoelectric generator component N, P is thermally and electrically conductively connected to a contact area 4′ of the first structured metallisation 4 and to a portion of the opposite contact area 5′ of the second structured metallisation 5. Here, the thermoelectric generator components N, P are preferably connected in series and produced from a thermoelectric semiconductor material, that is to say are provided in the form of Peltier elements, each of which comprises an n-doped semiconductor element N and a p-doped semiconductor element P. By way of example, bismuth telluride or silicon germanium or manganese silicon can be used as p- and n-doped semiconductor material. The use of materials based on the chemical compounds PbTe, SnTe, ZnSb or of material families of the scutterudites, clathrates and/or chalcogenides is also possible. The thickness of the semiconductor element N, P is between 0.5 mm and 8 mm, for example.

To generate electrical energy, the hot zone 1a of the thermoelectric generator module 1 is thermally conductively connected to a heat source, and the cold zone 1b of the thermoelectric generator module 1 is thermally conductively connected to a cold source, such that a temperature difference is produced between the opposite hot and cold zone 1a, 1b. With use of the thermoelectric generator module 1, the hot zone 1a is arranged for example in the exhaust gas zone of the motor vehicle, preferably thermally conductively connected directly or indirectly to the exhaust gas system of the motor vehicle. The cold zone 1b is preferably cooled and for this purpose is incorporated by way of example into the coolant circuit of the motor vehicle. Due to the temperature difference between the hot and cold zone 1a, 1b, a heat flow is produced through the thermoelectric generator module 1 and is converted by means of the thermoelectric generator components N, P into electrical energy.

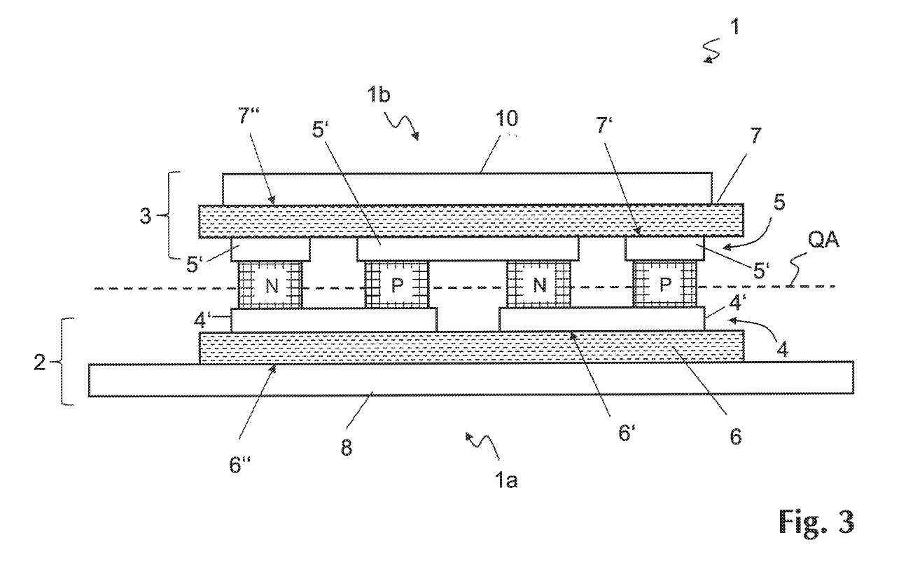

In the present exemplary embodiment according to FIGS. 1 and 3, at least one first metal-ceramic substrate 2 assigned to the hot zone 1a and one second metal-ceramic substrate 3 assigned to the cold zone 1b are provided. The invention, however, is in no way limited to two metal-ceramic substrates 2, 3 per thermoelectric generator module 1. Rather, a thermoelectric generator module 1 according to the invention may also comprise a plurality of such metal-ceramic substrate arrangements, also in stacked form.

The first metal-ceramic substrate 2 in the present exemplary embodiment has at least one first ceramic layer 6, to the surface side 6′ of which the first structured metallisation 4 is applied. Similarly hereto, the second metal-ceramic substrate 3 comprises at least one second ceramic layer 7, to the surface side 7′ of which the second structured metallisation 5 is applied. The layer thickness of the first and second ceramic layer 6, 7 is between 0.1 mm and 1 mm, preferably between 0.3 and 0.4 mm.

In accordance with the invention, the first metal-ceramic substrate 2 assigned to the hot zone 1a has at least one steel layer or high-grade steel layer 8, the first ceramic layer 6 being arranged between the first structured metallisation 4 and the at least one steel layer or high-grade steel layer 8.

In a preferred variant, the at least one steel layer or high-grade steel layer 8 is provided for thermally conductive connection to a further metal component, for example the exhaust of a vehicle. For simplified fastening, the at least one steel layer or high-grade steel layer 8 can protrude at least in portions beyond the edge of the first ceramic layer 6 in accordance with FIG. 3 and can thus form a fastening region for production of a soldered or welded connection and/or a detachable connection.

In a preferred exemplary embodiment according to FIGS. 1 and 3, the at least one steel layer or high-grade steel layer 8 is applied directly to the surface side 6″ of the first ceramic layer 6 opposite the first structured metallisation 4, more specifically by means of hard soldering, active soldering or adhesive bonding.

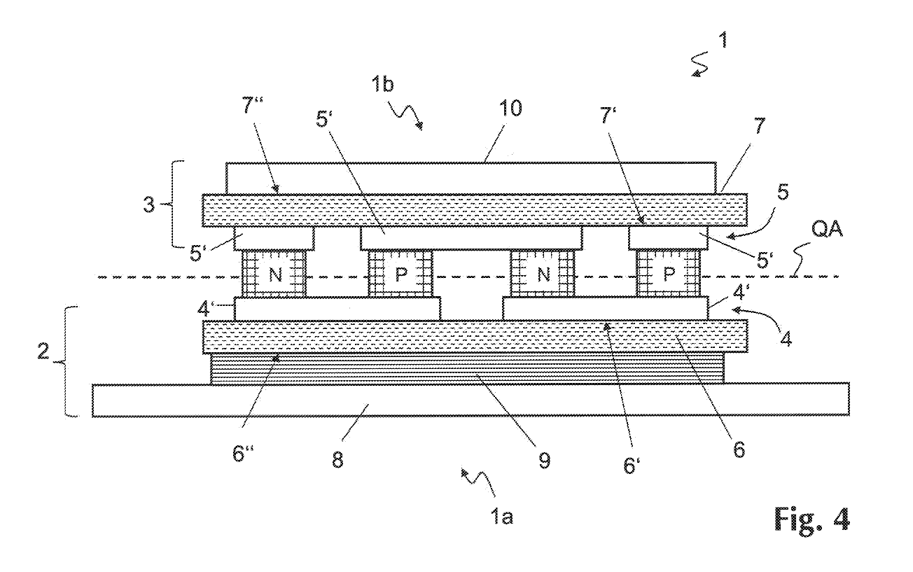

In an alternative variant according to FIG. 4, a copper layer 9 can be provided between the first ceramic layer 6 and the at least one steel layer or high-grade steel layer 8, the connection of the copper layer 9 to the surface side 6″ of the first ceramic layer 6 being produced preferably by the “direct-copper bonding” method or the AMP method. The copper layer 9 is connected to the steel layer or high-grade steel layer 8 by means of hard soldering or soft soldering or adhesive bonding, for example.

Further, the second metal-ceramic substrate 3 assigned to the cold zone 1b has at least one corrosion-resistant metal layer 10, preferably a high-grade steel layer, aluminium layer or copper layer, the corrosion-resistant metal layer 10 being applied to the surface side 7″ of the second ceramic layer 7 opposite the second structured metallisation 5. If the corrosion-resistant metal layer 10 is configured in the form of a copper layer, the connection can again be produced in a “direct-copper bonding” method or the AMB method, or, with configuration in the form of a high-grade steel layer or aluminium layer, by means of hard soldering, active soldering or adhesive bonding.

The metal contact areas 4′, 5′ formed by the first and second metallisation 4, 5 are preferably rectangular and each have two opposite longitudinal and broad sides a, b. These thus form what are known as pads for the connection of electronic components, more specifically the thermoelectric generator components N, P. To this end, a solder layer or solder is applied to the surface side of the metal contact areas 4′, 5′ opposite the ceramic layer 6, 7, and a soldered connection to the respective bond zone of the n- or p-doped semiconductor element N, P is produced, a metal bridge being produced between the n- and p-doped semiconductor element N, P in each case by one of the metal contact areas 4′, 5′, thus creating a Peltier element. The meandering course of the n- or p-doped semiconductor element N, P known per se and illustrated in the figures and of the metal contact areas 4′, 5′ connected thereto is thus produced.

To form the metal bridges, the longitudinal sides a of a rectangular metal contact area 4′, 5′ are approximately twice as long as the broad sides b of a rectangular metal contact area 4′, 5′, that is to say the longitudinal and broad sides a, b preferably have a ratio of 2:1. By way of example, the longitudinal side a is between 0.5 mm and 10 mm, and the broad side b is between 0.1 mm and 2 mm.

By way of example, a thermoelectric generator module 1 has a module longitudinal axis LA and a module transverse axis QA running perpendicularly hereto. In a preferred variant, the rectangular metal contact areas 4′, 5′ are arranged on the first or second ceramic layer 6, 7 in such a way that the longitudinal sides a of the rectangular metal contact areas 4′, 5′ run parallel to the module transverse axis QA, and the broad sides b of the rectangular metal contact areas 4′, 5′ run parallel to the module longitudinal axis LA. The first and second metal-ceramic substrate 2, 3 face one another here with their first and second structured metallisation 4, 5 in such a way that the rectangular metal contact areas 4′, 5′ are arranged with gaps therebetween, more specifically in such a way that, for example, by means of a rectangular metal contact area 5′ of the second structured metallisation 5, a metal bridge for an n- and p-doped semiconductor element N, P is formed, which are connected to two adjacent rectangular metal contact areas 4′ of the first structured metallisation 4. A series connection of a plurality of Peltier elements is thus formed along the columns S1 to Sy, the series connections of the Peltier elements in the columns S1 to Sy preferably being in turn connected to one another in series.

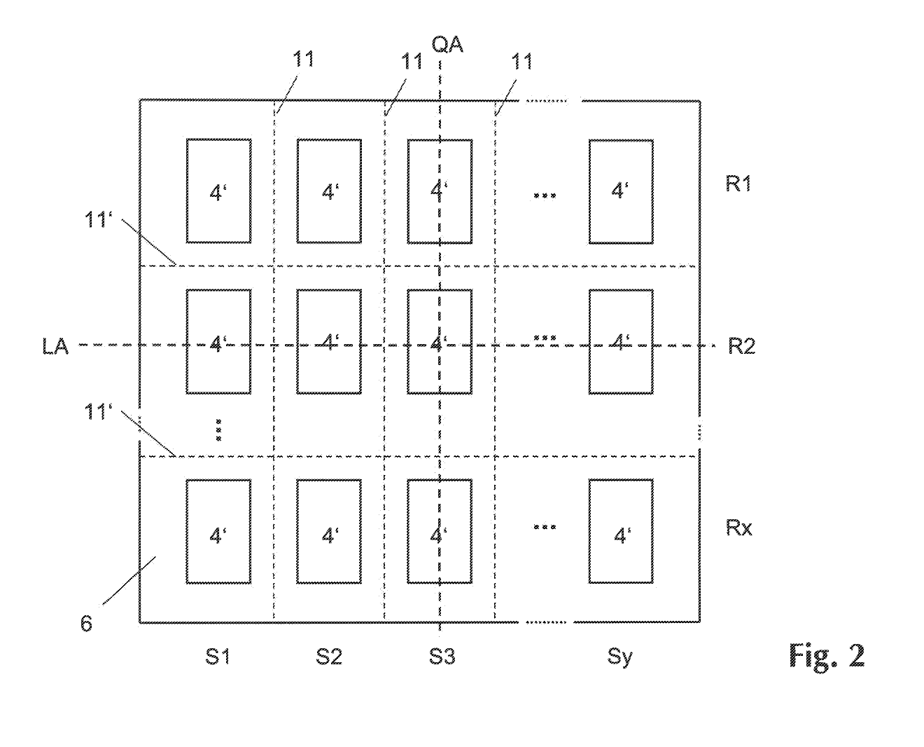

A schematic plan view of the contact areas 4′ of the first metal-ceramic substrate 2 is illustrated by way of example in FIG. 2, the rectangular metal contact areas 4′ preferably being arranged in a matrix-like manner on the surface side 6′ of the respective ceramic layer 6, more specifically in such a way that the rectangular metal contact areas 4′ form rows R1, R2, Rx running parallel to the module longitudinal axis LA and also columns S1, S2, S3, Sy running parallel to the module transverse axis QA. Cuboid metal contact areas 5′ may also be used optionally in the edge regions of the preferably rectangular first and/or second metal-ceramic substrate 2, 3, in which the connection of just one p- or n-doped semiconductor element P, N is necessary.

The contact areas 4′ assigned to a row R1, R2, Rx are distanced from one another and border one another via one of their longitudinal sides a. The distance c between two adjacent contact areas 4′ of a row R1, R2, Rx is between 0.1 mm and 2 mm by way of example, preferably between 0.4 mm and 0.6 mm.

Similarly, the contact areas 4′, 5′ assigned to a column S1, S2, S3, Sy are likewise arranged at a distance from one another on the respective ceramic layer 6, 7, more specifically for example at a distance d between 0.1 mm and 2 mm, preferably between 0.4 mm and 0.6 mm, two adjacent contact areas 4′, 5′ of a column S1, S2, S3, Sy bordering one another via one of their broad sides b.

Separation lines or predetermined break lines 11, 11′ are introduced in accordance with the invention into the ceramic layer 6, 7 between the rectangular metal contact areas 4′, 5′ arranged at a distance from one another on the respective ceramic layer 6, 7 and preferably run in the direction of the module transverse axis QA and/or in the direction of the module longitudinal axis LA. An area portion of the respective ceramic layer 6, 7 divided by separation lines or predetermined break lines 11, 11′ is therefore assigned to each rectangular metal contact area 4′, 5′, such that, in the case of a break of the ceramic layer 6, 7 along one or more separation lines or predetermined break lines 11, 11′, damage to the thermoelectric generator module 1 can be avoided.

The separation lines or predetermined break lines 11, 11′ can be provided in the form of slits, notches and/or scores and/or introduction of microcracks, which extend at least over a tenth of the layer thickness of the respective ceramic layer 6, 7 starting from the surface side 6′, 7′ receiving the metallisation 4′, 5′. The aforementioned recesses in the form of slits, notches and/or scores preferably have a depth from one quarter to three quarters of the layer thickness of the respective ceramic layer 6, 7, which may be between 0.1 mm and 1 mm.

The separation lines or predetermined break lines 11, 11′ are introduced into the ceramic layer 6, 7 after application of the structured metallisations 4, 5, preferably after completion of all soldering and bonding processes, for example more specifically by a laser treatment or a mechanical machining process, for example sawing. Laser-induced cutting methods or a thermal shock treatment are preferably used to introduce microcracks.

The ceramic layers 6, 7 consist by way of example of aluminium oxide (Al2O3) and/or aluminium nitride (AlN) and/or of silicon nitride (Si3N4) and/or of aluminium oxide with zirconium oxide (Al2O3+ZrO2). The first and second structured metallisations 4, 5 are preferably configured in the form of metal layers or metal foils, more specifically preferably from copper or a copper alloy. If the ceramic layers consist of one of the aforementioned ceramics (Al2O3, AlN, Si3N4, Al2O3+ZrO2), the metal layers or metal foils forming the structured metallisations 4, 5 are connected with use of the DCB method, more specifically in particular in the case of metallisations 4, 5 made of copper or copper alloys.

In addition, in a variant that is not illustrated, the metallisations 4, 5 can be provided at least in part with a metal, preferably corrosion-resistant surface layer, for example a surface layer consisting of nickel, silver or nickel alloys and silver alloys. A metal surface layer of this type is preferably applied, after the application of the metallisations 4, 5 to the ceramic layer 6, 7 and structuring thereof, to the rectangular metal contact areas 4′, 5′ thus produced. The surface layer is applied in a suitable method, for example galvanically and/or by chemical deposition and/or by spraying or cold gas spraying. In particular with use of nickel, the metal surface layer for example has a layer thickness in the range between 0.002 mm and 0.015 mm. With a surface layer consisting of silver, this is applied with a layer thickness in the range between 0.00015 mm and 0.05 mm, preferably with a layer thickness in the range between 0.01 μm and 3 μm. Due to a preferably corrosion-resistant surface coating of this type of the rectangular metal contact areas 4′, 5′, the application there of the solder layer or of the solder and the connection of the solder to the bonding zone of the thermoelectric generator components GB is improved.

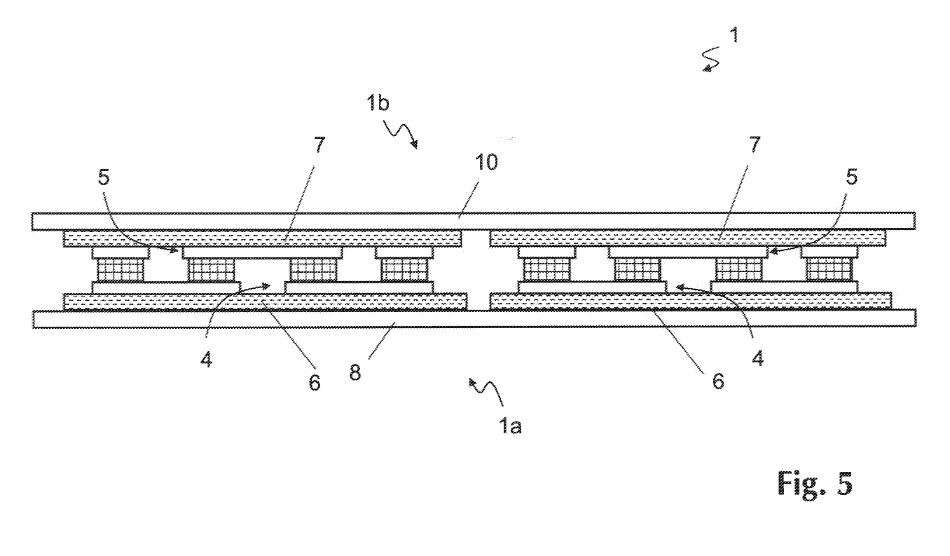

FIG. 5 shows a variant of a thermoelectric generator module 1 according to the invention in which two metal-ceramic substrate arrangements according to FIG. 1 are interconnected via a common steel layer or high-grade steel layer 8 and/or a common corrosion-resistant metal layer 10. Similarly, more than two metal-ceramic substrate arrangements of this type can also be connected via a common steel layer or high-grade steel layer 8 and/or a common corrosion-resistant metal layer 10. In an advantageous variant, a bead (not illustrated in FIG. 5), that is to say a channel-shaped depression produced manually or by machine, can be introduced between at least two successive metal-ceramic substrate arrangements, each forming a thermoelectric generator module 1, in the common steel layer or high-grade steel layer 8 and/or in the common corrosion-resistant metal layer 10 in order to compensate for thermal stresses.

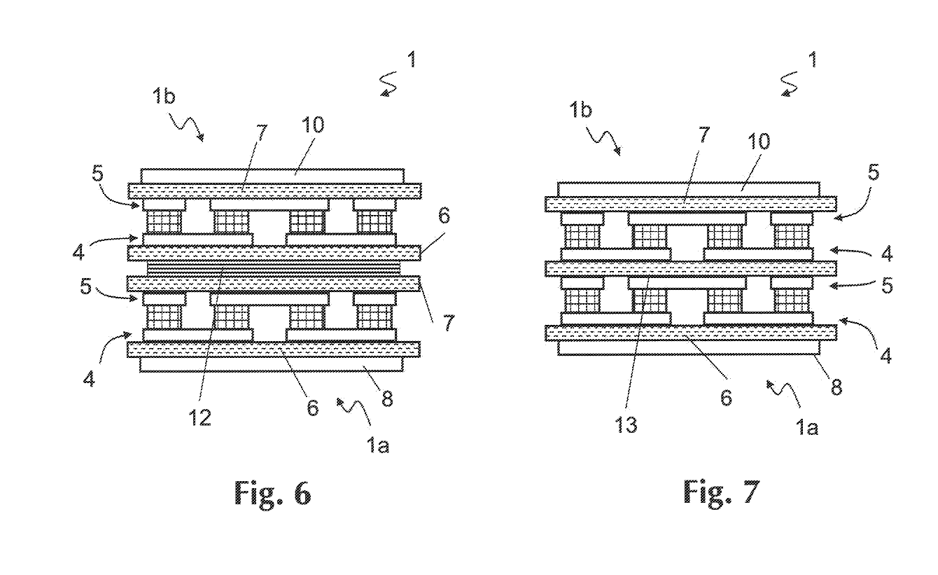

Two further variants of the thermoelectric generator module 1 according to the invention are illustrated in FIGS. 6 and 7 and have at least one composite substrate, which in each case basically comprises a stack of two metal-ceramic substrate arrangements according to FIG. 1. In the variant according to FIG. 6, the metal-ceramic substrate arrangements formed in accordance with FIG. 1 are interconnected via a common metal layer 12, preferably a copper layer. FIG. 7 shows a variant in which the first and second metallisation 6, 7 of the two metal-ceramic substrate arrangements are on a common ceramic layer 13.

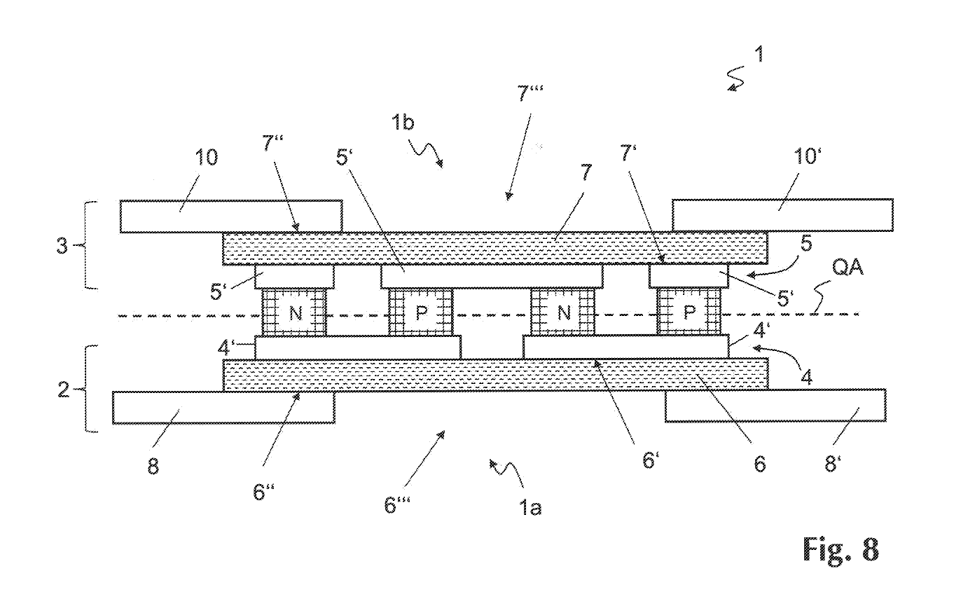

FIGS. 8 to 12 show different embodiments of the steel layer or high-grade steel layer 8 and/or of the corrosion-resistant metal layer 10 of a thermoelectric generator module 1 according to the invention.

A schematic sectional illustration through a thermoelectric generator module 1 is illustrated by way of example in FIG. 8, similarly to FIG. 3. However, the difference compared with FIG. 3 is that the steel layer or high-grade steel layer 8 and/or the corrosion-resistant metal layer 10 is/are formed in a number of parts, wherein the at least two steel layers or high-grade steel layers 8 and/or corrosion-resistant metal layers 10 created as a result are arranged at a distance from one another, and the surface sides 6″, 7″ of the first and second ceramic layer 6, 7 respectively are thus freely accessible at least in portions. At least one externally freely accessible surface portion 6′″, 7′″ of the first and second ceramic layer 6, 7 respectively is thus created. This enables an improved heat intake in the hot zone 1a and an improved cooling in the cold zone 1b. The at least two steel layers or high-grade steel layers 8 and/or corrosion-resistant metal layers 10 can preferably protrude outwardly via at least one edge region beyond the edge of the first and second ceramic layer 6, 7 and can thus form fastening potions.

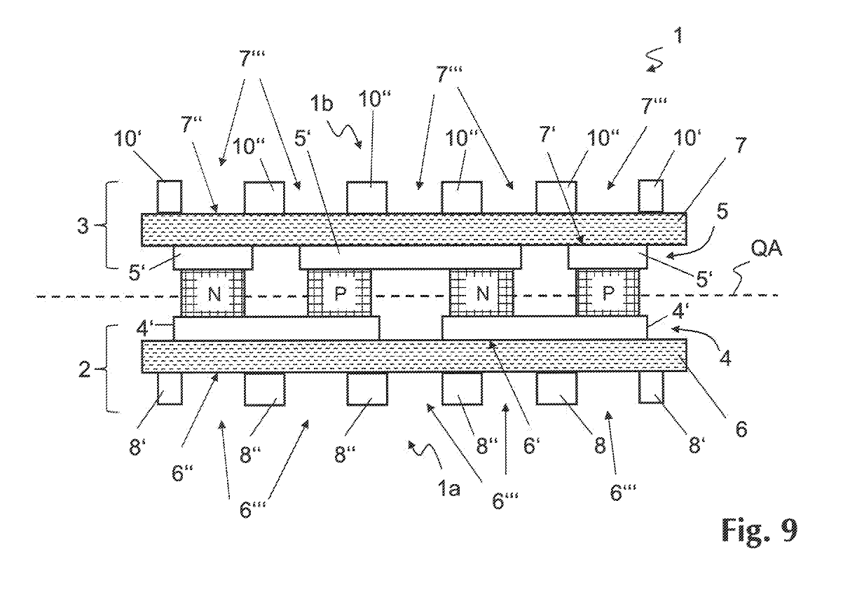

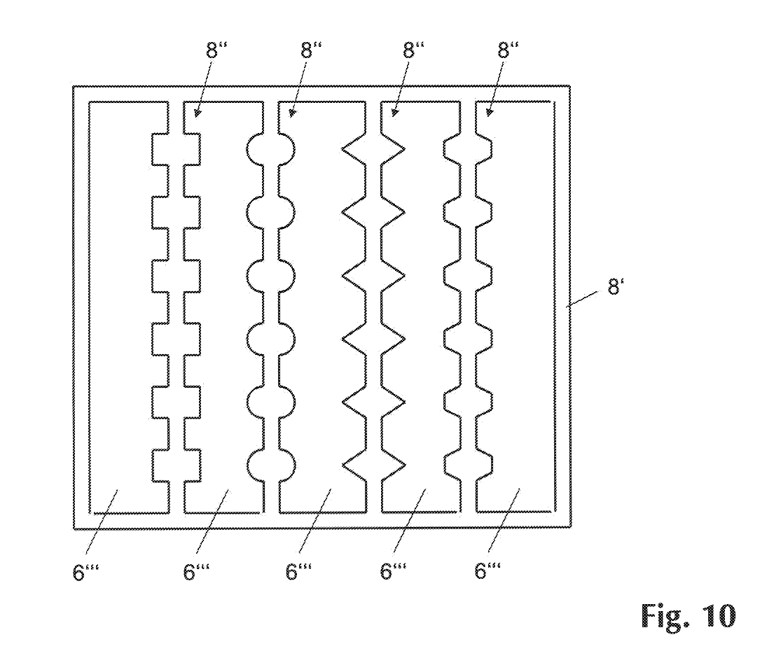

FIGS. 9 and 10 show a further alternative variant of the steel layer or high-grade steel layer 8 and/or of the corrosion-resistant metal layer 10, in which the steel layer or high-grade steel layer 8 and/or the corrosion-resistant metal layer 10 are formed in a grid-like manner in order to produce a plurality of freely accessible surface portions 6′″, 7′″. A schematic side view of a grid-like steel layer or high-grade steel layer 8 is illustrated in FIG. 10, in which case a plurality of different grid structures are provided by way of example. The grid structure can be formed by way of example by a peripheral, preferably rectangular frame portion 8′ and a plurality of connection web portions 8″, which run approximately parallel to one another and which may have convexities of different shape and/or size. By way of example, the convexities can be circular, triangular, rectangular, square or diamond-shaped. A grid-like steel layer or high-grade steel layer 8 or corrosion-resistant metal layer 10 of this type is preferably produced by punching, and is then connected to the surface side 6″, 7″ by adhesive bonding or soldering, wherein an adhesive portraying the grid structure or a solder portraying the grid structure is preferably applied to the surface side 6″, 7″ of the first and second ceramic layer 6, 7 respectively. A plurality of window-like freely accessible surface portions 6′″, 7′″ are produced by the described grid structure.

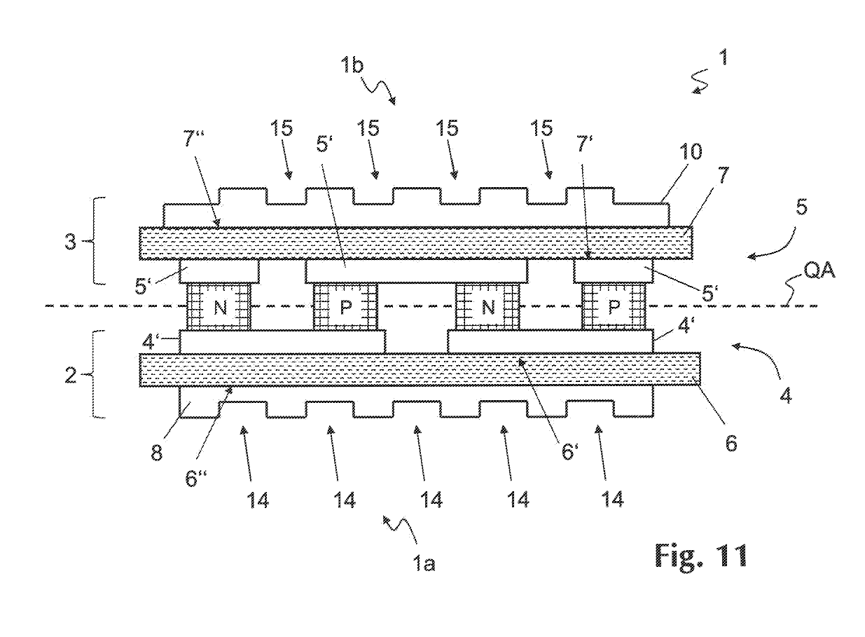

To increase the effective surface of the steel layer or high-grade steel layer 8 and/or of the corrosion-resistant metal layer 10, the steel layer or high-grade steel layer 8 and/or the corrosion-resistant metal layer 10 is/are profiled in the variant according to FIG. 11, that is to say recesses 14, 15 for example are introduced into the steel layer or high-grade steel layer 8 and/or the corrosion-resistant metal layer 10 in such a way that a number of rib-like surface portions are produced.

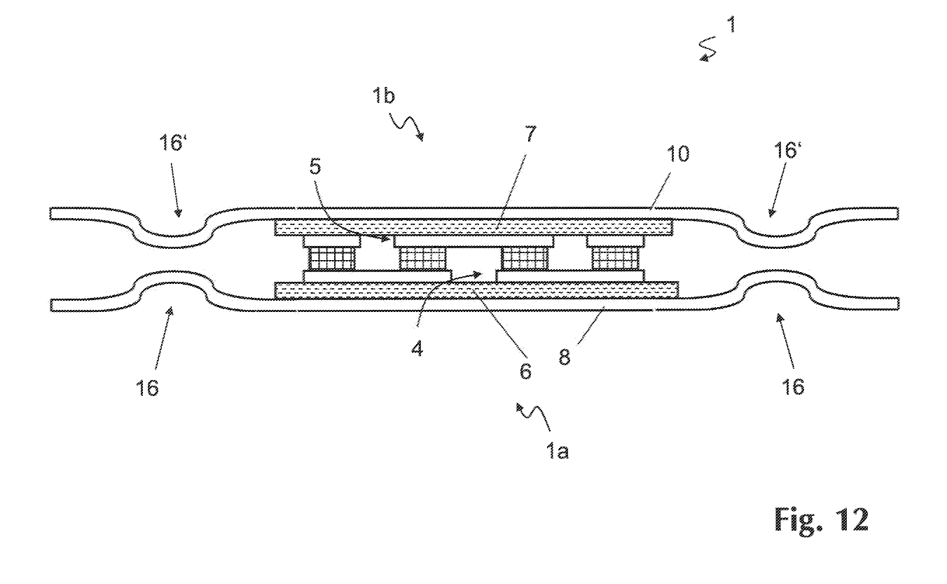

FIG. 12 shows a variant of the thermoelectric generator module 1, in which the steel layer or high-grade steel layer 8 and the corrosion-resistant metal layer 10 protrude outwardly beyond the edge regions of the first and second ceramic layer 6, 7, where they each have a peripheral bead 16, 16′, said beads preferably being directed towards one another. The free outer edges adjoining the peripheral beads 16, 16′ of the steel layer or high-grade steel layer 8 and of the corrosion-resistant metal layer 10 here again form fastening regions.

The steel layer or high-grade steel layer 8 is produced in a preferred variant from an alloyed steel with a proportion of molybdenum and/or nickel/cobalt. It is thus possible to adapt the coefficient of thermal expansion to the ceramic layer 6.

In particular, alloyed steel in the following composition can be used:
50%-60% iron
27%-31% nickel
15%-19% cobalt

By way of example, alloyed steel consisting of 54% iron, 29% nickel and 17% cobalt is particularly suitable.

The invention has been described above on the basis of exemplary embodiments. It goes without saying that numerous changes and modifications are possible without departing from the inventive concept forming the basis of the invention.

### LIST OF REFERENCE SIGNS

1 thermoelectric generator module
1a hot zone
1b cold zone
2 first metal-ceramic substrate
3 second metal-ceramic substrate
4 first structured metallisation
4′ contact areas
5 second structured metallisation
5′ contact areas
6 first ceramic layer
6′, 6″ surface sides
6′″ freely accessible surface portion
7 second ceramic layer
7′, 7″ surface sides
7, freely accessible surface portion
8 steel layer or high-grade steel layer
8′ frame portion
8, connection web portions
9 copper layer
10 corrosion-resistant metal layer
10′ frame portion
10″ connection web portions
11, 11′ separation lines or predetermined break lines
12 common metal layer
13 common ceramic layer
14 recess
15 recess
16, 16′ peripheral bead
a longitudinal sides
b broad sides
c spacing
d spacing
N, P thermoelectric generator component or n-/p-doped semiconductor element
LA module longitudinal axis
QA module transverse axis
R1, R2, Rx rows
S1, S2, S3 Sy columns

1. A thermoelectric generator module with a hot and cold zone (1a, 1b) comprising at least one first metal-ceramic substrate (2), which is assigned to the hot zone and has a first ceramic layer (6) and at least one structured first metallisation (4) applied to the first ceramic layer (6), and comprising at least one second metal-ceramic substrate (4), which is assigned to the cold zone (1b) and has a second ceramic layer (7) and at least one structured second metallisation (5) applied to the second ceramic layer, and also comprising a plurality of thermoelectric generator components (N, P) received between the first and second structured metallisation (4, 5) of the metal-ceramic substrates (2, 3), characterised in that the first metal-ceramic substrate (2) assigned to the hot zone (1a) has at least one steel layer or high-grade steel layer (8), the first ceramic layer (6) being arranged between the first structured metallisation (4) and the at least one steel layer or high-grade steel layer (8).

2. The module according to claim 1, characterised in that at least one copper layer (9) is provided between the first ceramic layer (6) and the at least one steel layer or high-grade steel layer (8).

3. The module according to claim 1 or 2, characterised in that the second metal-ceramic substrate (3) assigned to the cold zone (1b) has at least one corrosion-resistant metal layer (10), the second ceramic layer (7) being arranged between the second structured metallisation (5) and the corrosion-resistant metal layer (10).

4. The module according to claim 3, characterised in that the corrosion-resistant metal layer (10) is formed by a high-grade steel layer, aluminium layer or copper layer.

5. The module according to one of claims 1 to 4, characterised in that the first and second metallisation are structured in such a way that they form a plurality of metal contact areas (4′, 5′), which are preferably rectangular and/or cuboidal.

6. The module according to claim 5, characterised in that the longitudinal sides (a) of a rectangular metal contact area (4′, 5′) are approximately twice as long as the broad sides (b) thereof.

7. The module according to claim 5 or 6, characterised in that the longitudinal sides (a) of the rectangular metal contact areas (4′, 5′) run parallel to the module transverse axis (QA), and the broad sides (b) of the rectangular metal contact areas (4′, 5′) run parallel to the module longitudinal axis (LA).

8. The module according to one of claims 5 to 7, characterised in that the longitudinal sides (a) are between 0.5 mm and 10 mm, and the broad sides (b) are between 0.2 mm and 5 mm.

9. The module according to one of claims 5 to 8, characterised in that the metal contact areas (4′, 5′) are arranged in the matrix-like manner on the surface side of the respective ceramic layer (6, 7).

10. The module according to claim 9, characterised in that the rectangular metal contact areas (4′, 5′) form rows (R1, R2, Rx) running parallel to the module longitudinal axis (LA) and form columns (S1, S2, S3, Sy) running parallel to the module transverse axis (QA).

11. The module according to one of claims 5 to 10, characterised in that two adjacent rectangular metal contact areas (4′, 5′) have a spacing (d) from 0.1 mm to 2 mm in the direction of the module transverse axis (QA).

12. The module according to one of claims 5 to 11, characterised in that two adjacent rectangular metal contact areas (4′, 5′) have a spacing (c) from 0.1 mm to 2 mm in the direction of the module longitudinal axis (LA).

13. The module according to one of claims 5 to 12, characterised in that separation lines or predetermined break lines (11, 11′) are introduced into the ceramic layer (6, 7) between the rectangular metal contact areas (4′, 5′) arranged at a distance from one another on the respective ceramic layer (6, 7) and preferably run in the direction of the module transverse axis (QA) and/or in the direction of the module longitudinal axis (LA).

14. The module according to claim 13, characterised in that the separation lines or predetermined break lines (11, 11′) are produced in the form of slits, notches and/or scores and/or introduction of microcracks.

15. The module according to claim 14, characterised in that the slits, notches and/or scores of a separation line or predetermined break line (11, 11′) extend at least over a tenth of the layer thickness of the respective ceramic layer (6, 7) starting from the surface side (6′, 7′) of a ceramic layer (6, 7) receiving the metallisation (4, 5).

16. The module according to claim 14 or 15, characterised in that the slits, notches and/or scores of a separation line or predetermined break line (11, 11′) are produced by a laser treatment or mechanical machining of the ceramic layer (6, 7).

17. The module according to one of claims 1 to 16, characterised in that the ceramic layer (6, 7) is produced from aluminium oxide, aluminium nitride, silicon nitride or aluminium oxide with zirconium oxide, which preferably has a layer thickness in the range between 0.1 mm and 1.0 mm.

18. The module according to one of claims 1 to 17, characterised in that the first and second structured metallisation (4, 5) are configured in the form of metal layers or metal foils, more specifically preferably from copper or a copper alloy, which preferably have a layer thickness in the range between 0.03 mm and 1.5 mm.

19. The module according to one of claims 1 to 18, characterised in that the metallisations (4, 5) are provided at least in part with a metal surface layer, more specifically for example a surface layer made of nickel, silver or a nickel alloy or silver alloy.

20. The module according to one of the preceding claims, characterised in that the thermoelectric generator components (N, P) are configured in the form of Peltier elements produced from a differently doped semiconductor material, the thickness of the semiconductor material preferably being between 0.5 mm and 8 mm.

21. The module according to one of the preceding claims, characterised in that the steel layer or high-grade steel layer (8) and/or the corrosion-resistant metal layer (10) is/are formed in a number of parts, at least two parts of the steel layer or high-grade steel layer (8) and/or of the corrosion-resistant metal layer (10) being arranged at a distance from one another in such a way that at least one externally freely accessible surface portion (6′″, 7′″) of the ceramic layer (6, 7) is produced.

22. The module according to one of the preceding claims, characterised in that the steel layer or high-grade steel layer (8) and/or the corrosion-resistant metal layer (10) is structured or profiled.

23. The module according to one of the preceding claims, characterised in that the steel layer or high-grade steel layer (8) and/or the corrosion-resistant metal layer (10) has/have a peripheral bead (16, 16′) in a region protruding outwardly beyond the edge region the ceramic layer (6, 7).

24. A metal-ceramic substrate for use in a thermoelectric generator module (1) according to one of the preceding claims, comprising at least one ceramic layer (6) and at least one structured metallisation (4) applied to the ceramic layer (6), characterised in that the metal-ceramic substrate (2) has at least one steel layer or high-grade steel layer (8), the ceramic layer (6) being arranged between the structured metallisation (4) and the at least one steel layer or high-grade steel layer (8).

25. The metal-ceramic substrate according to claim 24, characterised in that at least one copper layer (9) is provided between the ceramic layer (6) and the at least one steel layer or high-grade steel layer (8).

26. The metal-ceramic substrate according to claim 24 or 25, characterised in that the metallisation (4) is structured in such a way that it forms a plurality of metal contact areas (4′), which are preferably rectangular and are arranged at a distance from one another.

27. The metal-ceramic substrate according to claim 26, characterised in that the longitudinal sides (a) of a rectangular metal contact area (4′, 5′) are approximately twice as long as the broad sides (b) thereof, the longitudinal sides (a) preferably being between 0.5 mm and 10 mm, and the broad sides (b) preferably being between 0.2 mm and 5 mm.

28. The metal-ceramic substrate according to claim 26 or 27, characterised in that the metal contact areas (4′) are arranged in a matrix-like manner on the surface side of the ceramic layer (6), more specifically in rows (R1, R2, Rx) and columns (S1, S2, S3, S4, Sy).

29. The metal-ceramic substrate according to one of claims 26 to 28, characterised in that separation lines or predetermined break lines (11, 11′) are introduced into the ceramic layer (6) between the metal contact areas (4′) and are preferably produced in the form of slits, notches and/or scores and/or introduction of microcracks.

30. The metal-ceramic substrate according to claim 29, characterised in that the slits, notches and/or scores of a separation line or predetermined break line (11, 11′) extend at least over a tenth of the layer thickness of the ceramic layer (6) starting from the surface side (6′) of a ceramic layer (6) receiving the metallisation (4).

31. The metal-ceramic substrate according to one of claims 24 to 30, characterised in that the ceramic layer (6) is produced from aluminium oxide, aluminium nitride, silicon nitride or aluminium oxide with zirconium oxide and preferably has a layer thickness in the range between 0.1 mm and 1.0 mm.

32. The metal-ceramic substrate according to one of claims 24 to 31, characterised in that the structured metallisation (4) is configured in the form of a metal layer or metal foil, more specifically preferably from copper or a copper alloy, which preferably has a layer thickness in the range between 0.03 mm and 1.5 mm.

33. The metal-ceramic substrate according to one of claims 24 to 32, characterised in that the metallisation (4) is provided at least in part with a metal surface layer, more specifically for example a surface layer made of nickel, silver or a nickel alloy or silver alloy.

34. A method for producing a metal-ceramic substrate (2), in particular in the form of a printed circuit board for a thermoelectric generator module (1), comprising at least one ceramic layer (6) and at least one structured metallisation (4) applied to the ceramic layer (6), characterised in that at least one steel layer or high-grade steel layer (8) is applied directly or indirectly to the surface (6′) opposite the ceramic layer (6, 7).

35. The method according to claim 34, characterised in that the metallisation (4) is structured in such a way that a plurality of metal contact areas (4′, 5′) are [symbol]
